(19) United States
(12) Patent Application Publication
(10) Pub. No.: US 2008/0278195 A1
(43) Pub. Date: Nov. 13, 2008

(54) STRUCTURE FOR EXECUTING SOFTWARE WITHIN REAL-TIME HARDWARE CONSTRAINTS USING FUNCTIONALLY PROGRAMMABLE BRANCH TABLE

(75) Inventors: Kenneth Goodnow, Essex, VT (US); Todd Edwin Leonard, Williston, VT (US); Jason M. Norman, Essex, VT (US); Clarence Ross Ogilvie, Huntington, VT (US); Peter Sandon, Essex Junction, VT (US); Charles Woodruff, Charlotte, VT (US)

Correspondence Address: SCULLY, SCOTT, MURPHY & PRESSER, P.C., 400 GARDEN CITY PLAZA, Suite 300, GARDEN CITY, NY, 11530, US

(73) Assignee: INTERNATIONAL BUSINESS MACHINES CORPORATION, Armonk, NY (US)

(21) Appl. No.: 12/118,234

(22) Filed: May 9, 2008

Related U.S. Application Data
(63) Continuation-in-part of application No. 11/745,657, filed on May 8, 2007.

(51) Int. Cl. H03K 19/173

(52) U.S. Cl. 326/38

(57) ABSTRACT

A computer system is disclosed which includes a design structure including a CPU or microprocessor to drive tightly constrained hardware events. The system comprises a processor having a set of system inputs to drive a functionally programmable event, and a fast branch in the CPU including a state handler to execute instructions from the CPU to process the event. A queue in the CPU stores the events such that the non-pre-empted events are serviced in the order they are received.

### CROSS-REFERENCE TO RELATED APPLICATION

This application is a continuation-in-part of co-pending and co-assigned U.S. patent application Ser. No. 11/745,657, filed May 8, 2007, currently pending.

### FIELD OF THE INVENTION

The invention relates to a design structure including universal processor architecture for a microprocessor, and more particularly, to a design structure for a branch controller in a microprocessor including a lookup table.

### BACKGROUND OF THE INVENTION

Currently, hardware intellectual property cores (IP cores) are costly to fix if a critical bug is found after printing to a chip. A semiconductor intellectual property core, (IP core or IP block) is a reusable unit of logic, cell, or chip layout design and is also the property of one party. IP cores can be used as building blocks within ASIC chip designs. A disadvantage to current bug fixing techniques includes necessitating a full respin (re-processing) of the chip, including a new mask set to fix the bug. To avoid this, the functional verification of the chip is done extensively before it's turned into hardware, and this verification may consume more development cost than the design itself. Software, although much more flexible and maintainable in terms of fixing bugs, works on a processor that, in essence, executes one small task at a time. The processor's serial nature makes it difficult to handle high speed hardware events that require nearly instant response time. Although multiple processors help increase the processing throughput, the interconnect and overhead involved with this can also be expensive, and may still require a respin of the hardware when a functional bug is fixed.

Further, typical real-time function queues need to interrupt processing to add a function to the queue. In addition, once the interrupt is implemented, the processor has to return from interrupt, get the next function in the queue, and jump to that function. Thus, undesirable processing time is required to implement such functions.

It would therefore be desirable to have a single processor on a chip that was able to service hardware events by their deadline, and would reduce development and verification costs. It would also be desirable to provide a much shorter process to fix, release, and distribute bug fixes.

### SUMMARY OF THE INVENTION

In an aspect according to the present invention, a functionally programmable branch controller system for a microprocessor comprises an instruction execution controller including a branch handler lookup table (LUT). A programmable logic block is embedded in an input-output (I/O) interface of the microprocessor to provide instruction address decode data to the branch handler when the programmable logic block receives a programmable event from a microprocessor.

In a related aspect, the programmable logic block may include a field programmable gate array (FPGA), and the controller system may further include a mask communicating with the programmable logic block and the execution controller, where the execution controller ignores an event specified by the mask.

In a related aspect, the microprocessor includes an execution unit which remains idle until the event from the execution controller is communicated to the execution unit.

In a related aspect, the execution unit jumps to an address of the event without saving a state of the event.

In a related aspect, the instruction execution controller further includes a state queue register communicating with the branch handler LUT for storing a plurality of events for execution by the LUT.

In a related aspect, the state queue register stores a plurality of events for sequential execution by the LUT in the order received.

In a related aspect, at least one of the plurality of events is preempted such that the preempted event is not executed in the order received.

In another aspect according to the invention, a method to enable a CPU to drive a series of tightly constrained hardware events comprises driving a functionally programmable event with a plurality of system inputs; executing a fast instruction branch in a CPU to a dedicated state machine to process the functionally programmable event; and idling a main program loop of the microprocessor without saving states when the functionally programmable event is complete and another functionally programmable event is not available.

In a related aspect, the method further comprises, before the step of idling the main program loop, servicing a plurality of events in their order of arrival.

In a related aspect, the method further comprises, before the step of idling the main program loop, servicing a plurality of events in their order of arrival unless preempted by an interrupt command.

In a related aspect, the method further comprises, before the step of idling the main program loop, servicing and storing a plurality of events in their order of arrival.

In a related aspect, the method further comprises preempting at least one of the plurality of events such that the preempted event is not executed in the order received.

In a related aspect, the method further includes masking bits in the dedicated state machine to prevent execution of a specified functionally programmable event.

In a related aspect, the method further comprises jumping to an address of the functionally programmable event without the execution unit saving a state of the event.

In another aspect according to the invention, a computer system includes a microprocessor to drive tightly constrained hardware events comprising a microprocessor having a set of system inputs to drive a functionally programmable event. A fast branch in the microprocessor includes a state handler to execute instructions from the microprocessor to process the event, and a queue in the microprocessor stores a plurality of event triggers such that non-pre-empted event triggers will be serviced in the order they are received.

In a related aspect, the state handler includes a lookup table (LUT).

In a related aspect, the fast branch in the microprocessor includes a programmable logic block communicating with the system inputs.

In a related aspect, the programmable logic block is a field programmable gate array (FPGA).

In a related aspect, the computer system further includes a specialized execution unit communicating with the queue in the microprocessor for executing the non-preempted event triggers.

In another aspect of the invention, a design structure includes a functionally programmable branch controller system for a microprocessor embodied in a machine readable medium for designing, manufacturing, or testing an integrated circuit, the design structure including an instruction execution controller including a branch handler lookup table (LUT), and a programmable logic block embedded in an input-output (I/O) interface of the microprocessor to provide instruction address decode data to the branch handler.

In a related aspect, the programmable logic block is a field programmable gate array (FPGA). The design structure may further include a mask communicating with the programmable logic block and the execution controller, and the execution controller ignores an event specified by the mask. The microprocessor includes an execution unit which remains idle until the event from the execution controller is communicated to the execution unit. The execution unit may jump to an address of the event without saving a state of the event. The instruction execution controller may further include a state queue register communicating with the branch handler LUT for storing a plurality of events for execution by the LUT. The state queue register may store a plurality of events for sequential execution by the LUT in the order received. One of the plurality of events may be preempted such that the preempted event is not executed in the order received. The design structure may comprise a netlist, and/or the design structure may reside on storage medium as a data format used for the exchange of layout data of integrated circuits, and/or the design structure may reside on a programmable gate array.

In another aspect of the invention, a computer system includes a design structure including a microprocessor to drive tightly constrained hardware events embodied in a machine readable medium for designing, manufacturing, or testing an integrated circuit (IC), the design structure includes a microprocessor having a set of system inputs to drive a functionally programmable event. The design structure further includes a fast branch in the microprocessor including a state handler to execute instructions from the microprocessor to process the event, and a queue in the microprocessor for storing a plurality of event triggers such that non-pre-empted event triggers will be serviced in the order they are received.

In a related aspect, the state handler may include a lookup table (LUT). The fast branch in the microprocessor may include a programmable logic block communicating with the system inputs. The programmable logic block may be a field programmable gate array (FPGA). The computer system may further include a specialized execution unit communicating with the queue in the microprocessor for executing the non-preempted event triggers. The design structure may comprise a netlist, and/or the design structure may reside on storage medium as a data format used for the exchange of layout data of integrated circuits, and the design structure may reside on a programmable gate array.

### BRIEF DESCRIPTION OF THE DRAWINGS

FIG. 1 is a block diagram of a CPU with a field programmable gate array (FPGA), execution controller, and specialized execution unit according to an embodiment of the present invention;

FIG. 2 is a process flow chart of the execution controller shown in FIG. 1;

FIG. 3 is a process flow chart of the specialized execution unit shown in FIG. 1; and

FIG. 4 is a flow diagram of a design process used in semiconductor designing, manufacture and/or testing.

### DETAILED DESCRIPTION OF THE INVENTION

An IP (intellectual property) core is generally a block of logic or data that may be used in making a field programmable gate array (FPGA) or application-specific integrated circuit for a product. Universal Asynchronous Receiver/Transmitter (UARTs), central processing units (CPUs), ethernet controllers, and PCI (Peripheral Component Interconnect) interfaces are examples of IP cores. An IP core library typically contains a multitude of unique designs that are costly to design, maintain, and migrate between technology nodes. However, an IP core library may serve a useful and vital role in an application-specific integrated circuit (ASIC) integrated circuit design function. In general, the present invention includes using a processor or multiple processors as a core or cores. The system and method of the present invention provides the original IP core library with a small set of generic software based microprocessor (uP) cores that are configurable to meet multiple core IP functions.

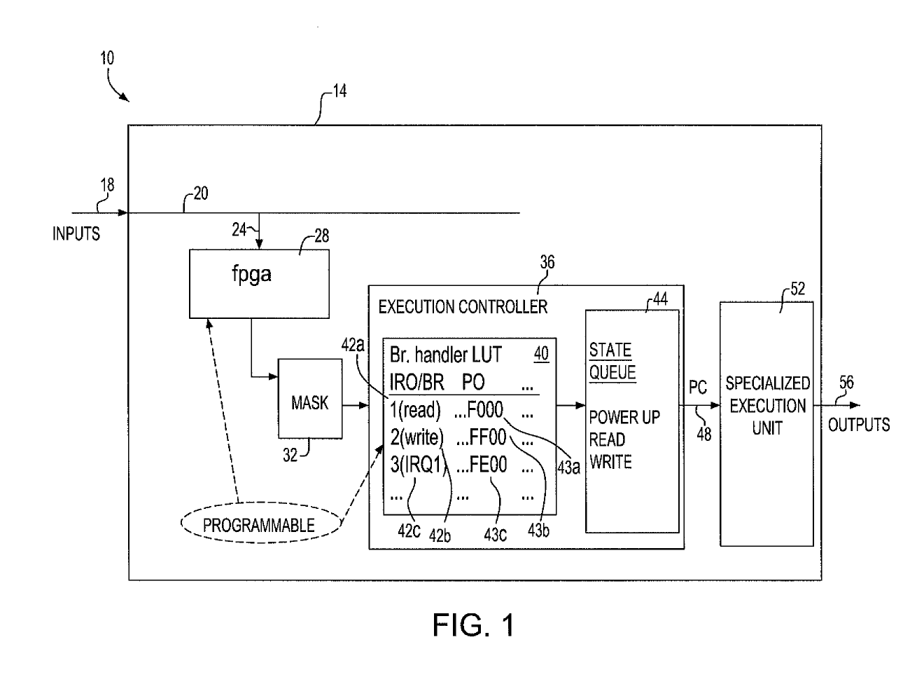

Referring to FIG. 1, an illustrative embodiment of a branch controller system 10 according to the present invention includes a central processing unit (CPU) or microprocessor 14 which receives system data inputs 18 that trigger a branch queue or fast branch 24. System data inputs 18 or a set of inputs drive a functionally programmable event. A data bus 20 communicates with the fast branch 24 of the system 10 which includes a field programmable gate array (FPGA) 28. The fast branch 24 is initiated using a functional logic, for example, embedding a small FPGA (field programmable gate array) 28 at the periphery of the CPU 14. Small FPGA logic can be embedded in a CPU input/output (I/O) interface and programmed by software to decode addresses, or input bit and route data to a branch handler/LUT (lookup table) 40. Also, FPGA logic can jump to a section of code on any configured logical function of inputs. Communicating with the FPGA is a mask 32 which functions as an interrupt scheme to ignore particular events, or the bits in the mask 32 can be set to have the CPU 14 ignore selected events. Thus, the mask 32 is logically positioned between the FPGA 28 and the execution controller 36.

Generally, an event signal will cause the fast branch 24 in the CPU 14 to communicate with a state handler (execution controller 36 shown in FIG. 1) that will execute the event's instructions and process the event. The FPGA can be programmed with logic and latches to trigger one of a fast branch event line. The event signal is sent through the mask 32, and then to a branch table or branch handler (lookup table (LUT) 40) that looks up exactly where the event handler is located. The branch table (LUT 40) queues the branch if the processor is already handling the event. Otherwise, the CPU 14 is triggered to branch to an event handler location immediately, without saving any context or states of the event in the LUT 40.

Referring to FIG. 1, an execution controller 36 communicates with the FPGA 28 and the mask 32, and includes a branch handler lookup table (LUT) 40. The FPGA 28 and the LUT 40 are programmable. The FPGA 28 is programmed after the manufacturing process to perform a specified logical function. Generally, a lookup table (LUT) is a data structure, usually an array or associative array, used to replace a runtime computation with a simpler lookup operation. Significant speed advantages can be made by using a lookup table because retrieving a value from memory is often faster than undergoing an expensive and time-consuming computation. The execution controller 36 further includes a state queue 44 communicating with the LUT 40 and communicating with a program counter (PC) 48 outside the execution controller 36. The event triggers are stored in the state queue 44 where non-pre-empted states will be serviced in the order received. The LUT 40 includes sample entries 42a, 42b, 42c referring to read, write, and interrupt commands, respectively, which correspond to addresses 43a, 43b, 43c, respectively. The LUT 40 enhances processing speed because each event inputted will have an entry in the LUT and communicate to the CPU the line number and memory location to handle that event. For example, event 42c is an interrupt request associated with the address 43c (FE00), and thus the execution unit 52 can execute the command. If more than one event is inputted concurrently i.e., before execution is completed on the previous event, the state queue 44 stores the events for processing in the order received.

A specialized execution unit 52, which is part of the CPU 14, receives input from the program counter (PC) 48 communicating an address for executing a command. The specialized execution unit 52 executes the command and generates an output 56.

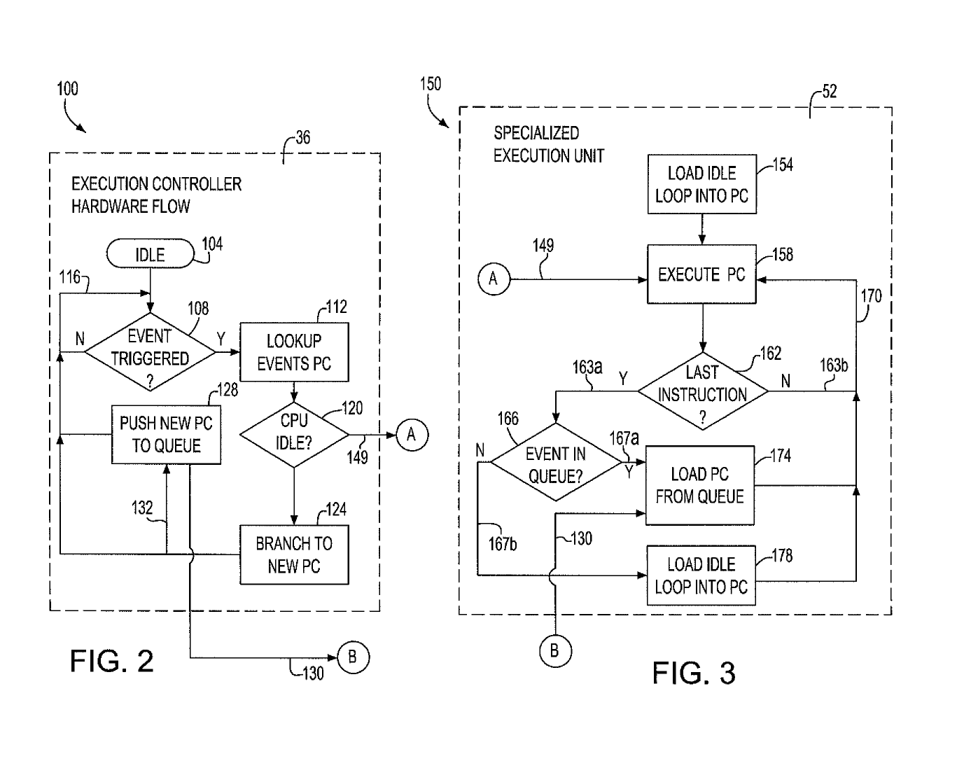

Referring to FIG. 2, an illustrative method of operation according to the present invention of the execution controller system 36 is depicted in flow chart 100 which includes an idle step 104 which requires the CPU to be in a specialized no-op branch loop. While the CPU/processor is in the no-op branch loop, the processor is effectively doing nothing except waiting for an event. A no-op branch loop generally refers to a CPU which is programmed to perform no operations except specified, i.e., a specialized operation.

More specifically, referring to FIGS. 2 and 3, the method shown in flowchart 100 includes a starting step or idle step 104 wherein the execution controller 36 (shown in FIG. 1) is in idle waiting for the FPGA 28 to receive an event to be communicated to the execution controller 36. The next step 108 determines if an event is triggered. If yes, the method goes to step 112 to generate the event's PC 48 using the handler/LUT 40 and the state queue 44, if necessary. If no, the method loops back 116 to before the inquiry of whether an event is triggered to reassess whether an event is triggered, essentially, in a loop until an event is triggered. After the method has completed the loop of the event's PC, the next step 120 ascertains whether the CPU or specialized execution unit 52 is idle, If yes, the method moves 149 to the specialized execution unit 52 of the CPU 14 which can execute the command in the specialized execution unit 52 (shown in FIG. 1, and in the flow chart in FIG. 3), and the method proceeds to branch to find a new PC 124 for a new event via path 116, or the method branches via path 132 to find a PC waiting in the queue 128. If the CPU is not idle, the method moves to step 128 to put the PC in the queue. The PC(s) in the queue are loaded 130 to the specialized execution unit 52 in step 174 to execute the PC in step 158 via path 170, as shown in FIG. 3. The PC(s) are in the queue in the order of arrival as described regarding the branch handler/LUT 40. Thus, as the CPU is available, a PC in the queue 128 is loaded from the queue 174 and executed 158.

Referring to FIGS. 1-3, an illustrative method 150 of the specialized execution unit 52 shown in FIG. 1 includes the step of executing a “no application” or “no-op” state, or loading an IDLE loop 154 so that the execution unit 52 is ready to receive and execute a PC address 158 from the execution controller 36 (FIG. 1) via 149 shown in FIG. 2. In idle 154, the CPU is in a specialized no-op branch loop so the processor is, effectively, doing nothing except waiting for an event. A no-op branch loop is where a CPU is programmed to perform no operations except when specified. The execution unit 52 is able to jump to the address instead of using a slower branch execution. The jump saves time and resources by bypassing saving, for example, state information, program location, or registers. The execution unit 52 jumps to the PC address without saving the address contents and executes the instructions at that address.

The next step of the method is to proceed to step 162 to determine if the last instruction was received. If yes 163a, the method proceeds to step 166 to determine if other events are in the queue. Time and processing savings are obtained using the method of the present invention because when the processor returns from an event handler, if there is another event in the queue to handle 167a, instead of returning to the idle loop, the processor jumps directly to the PC address (step 174) without going back to idle, and without saving context. The PC address is loaded 174 and executed 158. If no 163b, the method loops back via path 170 to step 158 to continue executing the current event until the last instruction is received. Once the last instruction is received 163a and there are no more events in the queue 166, the method proceeds via path 167b to step 178, which is the same as step 154, for the execution unit 52 to remain idle until a new PC is received via path 149 from steps 120 and 112.

An advantage of using the method according to the present invention is that less processing power and time is used than traditional processing techniques. The overhead expended to poll, mask, or calculate a particular condition, and multiple context switches are not required with this method, making hardware applications with a single CPU more feasible. Thus, real-time events can be handled with software on a single CPU. This allows traditional hardware designs to be run with software, and can also accelerate the hardware design schedule because a substantial amount of the verification can be done after the hardware skeleton is created.

Another advantage of the present invention is, in real-time operating systems, a “function queue” does not conflict with the “branch queue” of the present invention. Further, the branch queue of the present invention does not need to return from interrupt, does not need a context save, and can branch directly to the next state without returning to the main loop. Thus, several cycles of overhead are avoided. More specifically, the branch queue holds event addresses to which the CPU must branch, in order to handle the given event. When a new hardware event occurs, the address of the event handler is found in the LUT and goes directly to the top of the branch queue. The CPU looks at the top of this branch queue when it is idle, or returns from another event handler. If there is an event to handle (i.e., there is an address in the queue), the CPU will process the address from the queue and jump (branch) directly to that address.

The branch controller system of the present invention emulates hardware behavior with software on a processor. The processor 52 in the specialized execution unit runs significantly faster than the frequency of hardware events inputted 18. For example, if the external hardware bus 18 runs at 1 GHz, the processor inside the specialized execution unit 52, may run, for example, at 10 GHz, giving the processor inside the specialized execution unit 10 cycles to handle the hardware events. For example, assuming one instruction is executed per CPU clock cycle, and the processor 52 is 10 times faster than the hardware events, the cycle differential between the processor 52 and the hardware events results in the specialized execution unit 52 having 10 cycles as a deadline to finish any work before the next event is inputted.

Generally in a microprocessor, response time is critical to bus transactions, and thus it is necessary to respond to an event by the deadline associated with it. In the embodiment shown in FIGS. 1-3, each event has its own deadline, thus, the event's order of arrival time serves as its priority. Thus, events are added in the order received to the branch queue/branch handler 40. However, there may be exceptions. If, for example, a high priority error occurs, a secondary hardware mechanism can force the event handler 40 to call the next event in the queue, i.e., essentially stepping a selected event forward to the front of the queue. To do this, a set of events (branch conditions) could be stored in a lookup table with priorities associated with each one. It's also possible that an error can make the states following the error in the queue no longer valid.

Further, for states that are not subject to a strict, short deadline, the lookup table 40 can also hold a value to indicate whether the state/event can be preempted by another routine. However, to avoid the overhead of context switching, all preemption may be disallowed by default.

In another example of an error, an event handler may fail to respond to an event and return by the deadline. This could happen, for example, because of hardware issues (e.g., power states, clocking errors) or programmer errors. This type of error may be severe and unrecoverable. However, if it is detected that a deadline will be missed, it's possible that the root problem can be fixed and normal operation can resume. To detect a deadline miss, another hardware device will determine how long a particular event handler is processing, and compare it to the predetermined deadline for the response. This predetermined deadline will be loaded into a deadline detector from the same lookup table, at the start of a state branch. An exemplary lookup table, Table 1, is shown below.

| State | Address | Priority | Preempted | Deadline |
|---|---|---|---|---|
| I2C_READ | A0_FFC0 | 0 (none) | No | 18 (cycles) |
| I2C_WRITE | A0_FFE0 | 0 | No | 13 |
| OPB_READ | E0_00B8 | 0 | No | 8 |
| OPB_WRITE | E0_00E0 | 0 | No | 5 |
| ADDR_ERR | D0_0000 | 5 | No | 9 |

Another advantage of the present invention is the ability to make software implementation of hardware more practical. For example, in the present invention, the software is easily maintainable, for example in the case of fixing errors, which reduces costs of support and version redelivery. More specifically, designing hardware for manufacturing on a chip is a long and expensive process. If a defect is found in the product after it has been manufactured, the entire process (e.g., verification, synthesis, layout, checking, mask fabrication, photolithography, etc.) needs to start again, and could cause the product to miss its market window. To avoid this, extensive logic verification of the design is completed before it is released to manufacturing to remove as many bugs (problems/defects) as possible. The cost of verification is roughly twice the cost of designing the chip, and with increasing complexity the cost of verification is increasing exponentially. If the products logic function, however, is done in software, in accordance with the present invention, defects can simply be delivered directly to the customer (for example, downloaded into a computer's RAM). This solution to a bug is thereby rapid and cost efficient, compared to a full hardware respin.

Additionally, the method according to the present invention differs from an interrupt operation. An interrupt operation is used by an operating system and has the ability to handle multiple interrupts concurrently. The method of the present invention differs by having a queue of next states, where each state is in a branch location. The method further includes an automatic return to idle, and a branch to register. No preemption is allowed, a sequence must be finished that is running, then the next task in the queue is run that may include a hardware task queue which is built on demand.

Moreover, function queues according to the present invention include an (interrupt service routine) ISR which adds a function pointer to the function queue in real-time embedded systems. The pointer simply points to a function that services the interrupt. The main loop of the program grabs the latest function from the queue and calls that function.

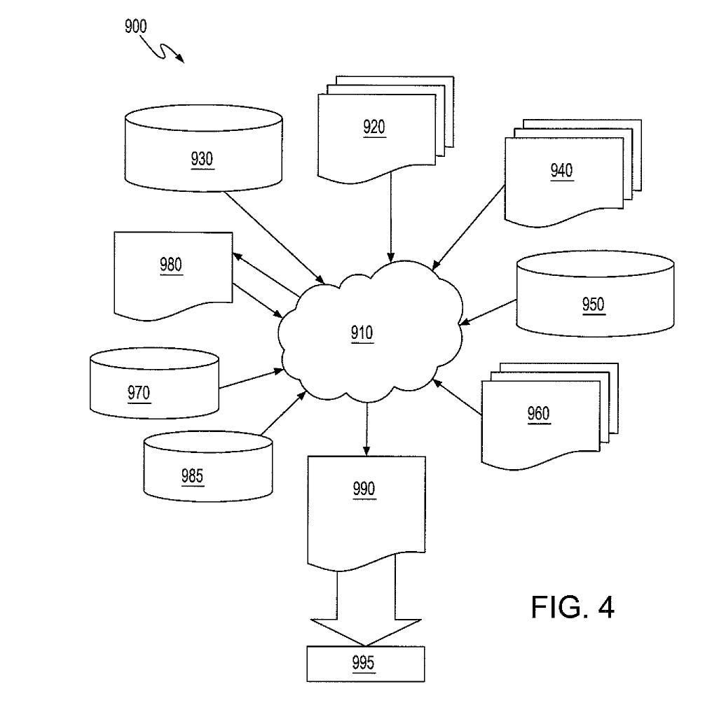

FIG. 4 shows a block diagram of an exemplary design flow 900 used for example, in semiconductor design, manufacturing, and/or test. Design flow 900 may vary depending on the type of IC being designed. For example, a design flow 900 for building an application specific IC (ASIC) may differ from a design flow 900 for designing a standard component or from a design from 900 for instantiating the design into a programmable array, for example a programmable gate array (PGA) or a field programmable gate array (FPGA) offered by Altera® Inc. or Xilinx® Inc. Design structure 920 is preferably an input to a design process 910 and may come from an IP provider, a core developer, or other design company or may be generated by the operator of the design flow, or from other sources. Design structure 920 comprises an embodiment of the invention as shown in FIGS. 1-3 in the form of schematics or HDL, a hardware-description language (e.g., Verilog, VHDL, C, etc.). Design structure 920 may be contained on one or more machine readable medium. For example, design structure 920 may be a text file or a graphical representation of an embodiment of the invention as shown in FIGS. 1-3. Design process 910 preferably synthesizes (or translates) an embodiment of the invention as shown in FIGS. 1-3 into a netlist 980, where netlist 980 is, for example, a list of wires, transistors, logic gates, control circuits, I/O, models, etc. that describes the connections to other elements and circuits in an integrated circuit design and recorded on at least one of machine readable medium. For example, the medium may be a CD, a compact flash, other flash memory, a packet of data to be sent via the Internet, or other networking suitable means. The synthesis may be an iterative process in which netlist 980 is resynthesized one or more times depending on design specifications and parameters for the circuit.

Design process 910 may include using a variety of inputs; for example, inputs from library elements 930 which may house a set of commonly used elements, circuits, and devices, including models, layouts, and symbolic representations, for a given manufacturing technology (e.g., different technology nodes, 32 nm, 45 nm, 90 nm, etc.), design specifications 940, characterization data 950, verification data 960, design rules 970, and test data files 985 (which may include test patterns and other testing information). Design process 910 may further include, for example, standard circuit design processes such as timing analysis, verification, design rule checking, place and route operations, etc. One of ordinary skill in the art of integrated circuit design can appreciate the extent of possible electronic design automation tools and applications used in design process 910 without deviating from the scope and spirit of the invention. The design structure of the invention is not limited to any specific design flow.

Design process 910 preferably translates an embodiment of the invention as shown in FIGS. 1-3, along with any additional integrated circuit design or data (if applicable), into a second design structure 990. Design structure 990 resides on a storage medium in a data format used for the exchange of layout data of integrated circuits and/or symbolic data format (e.g. information stored in a GDSII (GDS2), GL1, OASIS, map files, or any other suitable format for storing such design structures). Design structure 990 may comprise information such as, for example, symbolic data, map files, test data files, design content files, manufacturing data, layout parameters, wires, levels of metal, vias, shapes, data for routing through the manufacturing line, and any other data required by a semiconductor manufacturer to produce an embodiment of the invention as shown in FIGS. 1-3. Design structure 990 may then proceed to a stage 995 where, for example, design structure 990: proceeds to tape-out, is released to manufacturing, is released to a mask house, is sent to another design house, is sent back to the customer, etc.

While the present invention has been particularly shown and described with respect to preferred embodiments thereof, it will be understood by those skilled in the art that changes in forms and details may be made without departing from the spirit and scope of the present application. It is therefore intended that the present invention not be limited to the exact forms and details described and illustrated herein, but falls within the scope of the appended claims.

What is claimed is:

1. A design structure including a functionally programmable branch controller system for a microprocessor embodied in a machine readable medium for designing, manufacturing, or testing an integrated circuit, the design structure comprising:
an instruction execution controller including a branch handler lookup table (LUT); and
a programmable logic block embedded in an input-output (I/O) interface of the microprocessor to provide instruction address decode data to the branch handler.

2. The design structure of claim 1, wherein the programmable logic block is a field programmable gate array (FPGA).

3. The design structure of claim 1, further including a mask communicating with the programmable logic block and the execution controller, and the execution controller ignores an event specified by the mask.

4. The design structure of claim 1, wherein the microprocessor includes an execution unit which remains idle until the event from the execution controller is communicated to the execution unit.

5. The design structure of claim 4, wherein the execution unit jumps to an address of the event without saving a state of the event.

6. The design structure of claim 1, wherein the instruction execution controller further includes a state queue register communicating with the branch handler LUT for storing a plurality of events for execution by the LUT.

7. The design structure of claim 6, wherein the state queue register stores a plurality of events for sequential execution by the LUT in the order received.

8. The design structure of claim 7, wherein at least one of the plurality of events is preempted such that the preempted event is not executed in the order received.

9. The design structure of claim 1, wherein the design structure comprises a netlist.

10. The design structure of claim 1, wherein the design structure resides on storage medium as a data format used for the exchange of layout data of integrated circuits.

11. The design structure of claim 1, wherein the design structure resides on a programmable gate array.

12. A computer system including a design structure including a microprocessor to drive tightly constrained hardware events embodied in a machine readable medium for designing, manufacturing, or testing an integrated circuit (IC), the design structure comprising:
a microprocessor having a set of system inputs to drive a functionally programmable event;
a fast branch in the microprocessor includes a state handler to execute instructions from the microprocessor to process the event; and
a queue in the microprocessor for storing a plurality of event triggers such that non-pre-empted event triggers will be serviced in the order they are received.

13. The computer system of claim 12, wherein the state handler includes a lookup table (LUT).

14. The computer system of claim 12, wherein the fast branch in the microprocessor includes a programmable logic block communicating with the system inputs.

15. The computer system of claim 14, wherein the programmable logic block is a field programmable gate array (FPGA).

16. The computer system of claim 12, further including a specialized execution unit communicating with the queue in the microprocessor for executing the non-preempted event triggers.

17. The design structure of claim 12, wherein the design structure comprises a netlist.

18. The design structure of claim 12, wherein the design structure resides on storage medium as a data format used for the exchange of layout data of integrated circuits.

19. The design structure of claim 12, wherein the design structure resides on a programmable gate array.
